(19) United States
(12) Patent Application Publication
(10) Pub. No.: US 2025/0218921 A1
(43) Pub. Date: Jul. 3, 2025

(54) THERMALLY CONDUCTIVE SUPPORT AND ASSEMBLY COMPRISING A THERMALLY CONDUCTIVE SUPPORT AND A PACKAGED POWER DEVICE

(71) Applicant: STMicroelectronics International N.V., Geneva (CH)

(72) Inventors: Cristiano Gianluca STELLA, San Gregorio di Catania (IT); Francesco SALAMONE, ACIREALE (IT); Marco PAPASERIO, Misterbianco (IT)

(21) Appl. No.: 18/984,349

(22) Filed: Dec. 17, 2024

(30) Foreign Application Priority Data
Jan. 2, 2024 (IT) 102024000000018

(51) Int. Cl. H01L 23/498; H01L 23/00; H01L 23/373

(52) U.S. Cl. CPC H01L 23/49861; H01L 23/3735; H01L 24/32; H01L 2224/32237

(57) ABSTRACT

Various embodiments of thermally conductive support are provided. An example thermally conductive support includes a core layer, of metal, a dielectric layer, extending on a first face of the core layer and an electrical connection layer, of electrically conductive material, extending on the first dielectric layer. The dielectric layer has a through hole which exposes the core layer and is intended to be filled with an adhesive mass having an electronic power device adhering thereto, forming a device/support assembly.

### CROSS REFERENCE TO RELATED APPLICATION(S)

This application claims the priority benefit of Italian Patent Application Number 102024000000018, filed on Jan. 2, 2024, entitled “Supporto Termicamente Conduttivo E Assieme Comprendente Un Substrato Termicamente Conduttivo Ed Un Dispositivo Elettronico Di Potenza Incapsulato”, which is hereby incorporated by reference to the maximum extent allowable by law.

### TECHNICAL FIELD

The present disclosure relates to a thermally conductive support and to an assembly comprising a thermally conductive support and a packaged electronic power device. In particular, the packaged electronic power device is a dual-side cooling device for high thermal dissipation.

### BACKGROUND

As is known, high-voltage and/or high-current power semiconductor devices (for example superjunction transistors with a silicon substrate, vertical transistors with a silicon carbide (SiC) or silicon (Si) substrate, planar MOSFET transistors, for example based on gallium nitride (GaN), IGBTs (Insulated-Gate Bipolar Transistor) and similar are widely used in applications, for example for power conversion, where they are subject to high or very high voltage biasing (with values even up to 1000-2000 V) and are flown through by currents which may switch rapidly.

These devices are packaged so that the final device has a high electrical insulation, has a suitable separation distance between the leads associated with the terminals and allows high heat dissipation towards the outside.

The packaged devices are bonded to supports or substrates also designed so as to dissipate as much as possible the heat generated by the packaged device during operation.

To this end, printed circuit boards, PCBs, are currently often used and provided with thermal vias (i.e. thermally conductive regions, for example of metal) which traverse the boards to facilitate the removal of heat also from the lower side (bonded to the substrate) of the packaged power device.

Another substrate currently used in applications where very high thermal dissipation is desired is the so-called Insulated Metal Substrate, IMS, support.

An IMS support is formed by a metal tile covered, on one or both sides, by a dielectric layer, as shown for example in FIG. 1 and described hereinbelow.

The IMS support of FIG. 1, identified by 1, comprises a core layer 2, of metal such as aluminum, copper or steel, having a high thickness (for example comprised between 0.5 mm and 1.5 mm) overlaid by a thin dielectric layer 3, for example a non-reinforced or glass-reinforced epoxy laminate such as FR-4 or a pre-peg, with a thickness typically comprised between 38 μm and 225 μm.

The thin dielectric layer 3 is generally covered by a thin connection layer 4, of metal such as copper, with a thickness typically comprised between 17 μm and 600 μm, which is patterned to form electrical connections, any dissipation pads and/or other metal structures.

A lower dielectric layer 5, similar to the thin dielectric layer 3, here extends on the back side of the core layer 2, but is sometimes removed.

IMS supports considerably improve the back thermal dissipation capacities of packaged power devices; nonetheless, such dissipative capacity is not always sufficient.

The aim of the present disclosure is to provide a solution that allows improving thermal dissipation.

### BRIEF SUMMARY

According to the present disclosure, a thermally conductive support and a device/support assembly are provided, as defined in the attached claims.

### BRIEF DESCRIPTION OF THE DRAWINGS

For a better understanding of the present disclosure, some embodiments thereof are now described, purely by way of non-limiting example, with reference to the attached drawings, wherein:

FIG. 1 is a top perspective view of a known commercial IMS support;

FIG. 2 is a top perspective view of an IMS support according to one embodiment;

FIG. 3 is a cross-section of the IMS support of FIG. 2;

FIG. 4 is a cross-section of an assembly comprising the IMS support of FIG. 2 and a packaged power device;

FIG. 5 is a top perspective view of the assembly of FIG. 4;

FIG. 6 is a top perspective view of the IMS support used in the assembly of FIGS. 4 and 5, in an intermediate processing step;

FIG. 7 is a cross-section of another assembly comprising the IMS support of FIG. 2 and another packaged power device;

FIG. 8 is a top perspective view of the assembly of FIG. 7;

FIG. 9 is a top perspective view of the IMS support used in the assembly of FIGS. 7 and 8, in an intermediate processing step;

FIG. 10 is a cross-section of a different assembly comprising the IMS support of FIG. 2 and the packaged power device of FIG. 4, with a different bonding configuration;

FIG. 11 is a top perspective view of the IMS support used in the assembly of FIG. 10, in an intermediate processing step;

FIG. 12 is a cross-section of a different assembly comprising the IMS support of FIG. 2 and the packaged power device of FIG. 4, with another bonding configuration;

FIG. 13 is a top perspective view of the IMS support used in the assembly of FIG. 12, in an intermediate processing step;

FIG. 14 is a top perspective view of an assembly formed by a packaged electronic module and the IMS support of FIG. 2;

FIG. 15 is a cross-section of the assembly of FIG. 14, taken along section line XV-XV;

FIG. 16 shows an enlarged detail of the assembly of FIGS. 14 and 15, taken along section line XVI-XVI of FIG. 14;

FIG. 17 is a top perspective view of the IMS support used in the assembly of FIGS. 14-16, in an intermediate processing step;

FIG. 18 is a top perspective view of a cooled system, comprising a cooling plate and an assembly formed by an IMS support and a packaged electronic module;

FIG. 19 is a perspective cross-section of the cooled system of FIG. 18, taken along section line XIX-XIX;

FIG. 20 is a perspective cross-section of the cooled system of FIG. 18, taken along section line XX-XX;

FIG. 21 is a cross-section of another cooled system; and

FIG. 22 shows the cooled system of FIG. 21 in a different fluidic configuration.

### DETAILED DESCRIPTION

The following description refers to the arrangement shown; consequently, expressions such as “above”, “below”, “upper”, “lower”, “right”, “left” relate to the attached Figures and are not to be interpreted in a limiting manner.

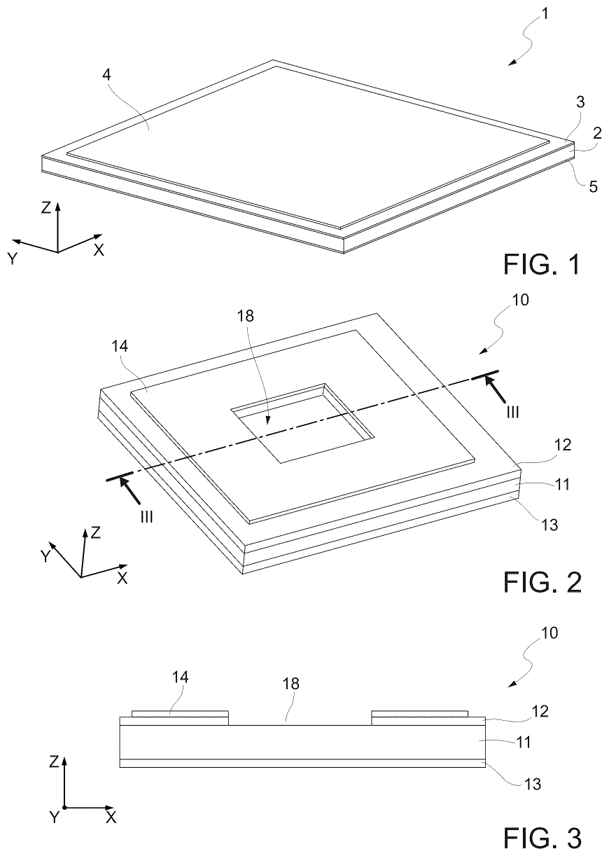

FIGS. 2 and 3 show an IMS support 10 having a base structure similar to the IMS support 1 of FIG. 1 and therefore formed by a core layer 11, of high-thermally conducting metal, covered, on a first side, by an upper dielectric layer 12 and, on a second side, by a lower dielectric layer 13. In some applications the lower dielectric layer 13 may not be present.

A connection layer 14, of metal, extends above the upper dielectric layer 12 and is intended to form connections, dissipation pads and/or other metal structures.

The core layer 11, typically of copper, aluminum or steel, has a high thickness (for example comprised between 0.5 and 1.5 mm); the upper dielectric layer 12 and the lower dielectric layer 13 are formed by, for example, a glass-reinforced epoxy laminate such as the FR-4 or a pre-peg, with a thickness typically comprised between 100 μm and 300 μm; and the connection layer 14 is typically of copper, with a thickness comprised for example between 17 μm and 600 μm.

The IMS support 10 has main dimensions in a plane parallel to a Cartesian plane XY of a Cartesian reference system XYZ, and a thickness (in a direction parallel to a vertical axis Z of the Cartesian reference system XYZ) given by the sum of the thicknesses of the layers 11-14.

The connection layer 14 and the upper dielectric layer 12 are partially removed, here in a substantially central position and in any case in a suitable position, as discussed below, and form a hole 18, which exposes the core layer 11.

The hole 18, formed for example through a photolithographic process, is intended to be filled with bonding material, that is thermally conductive, such as solder paste, which allows a direct thermal connection with a power device or module to be soldered on the IMS support 10 and for which it is desired to have high thermal loss.

The area (in the main extension plane of the IMS support 10) and the position of the hole 18 in the main extension plane are chosen based on the particular device or module to be attached, as shown in some embodiments, described in detail hereinbelow.

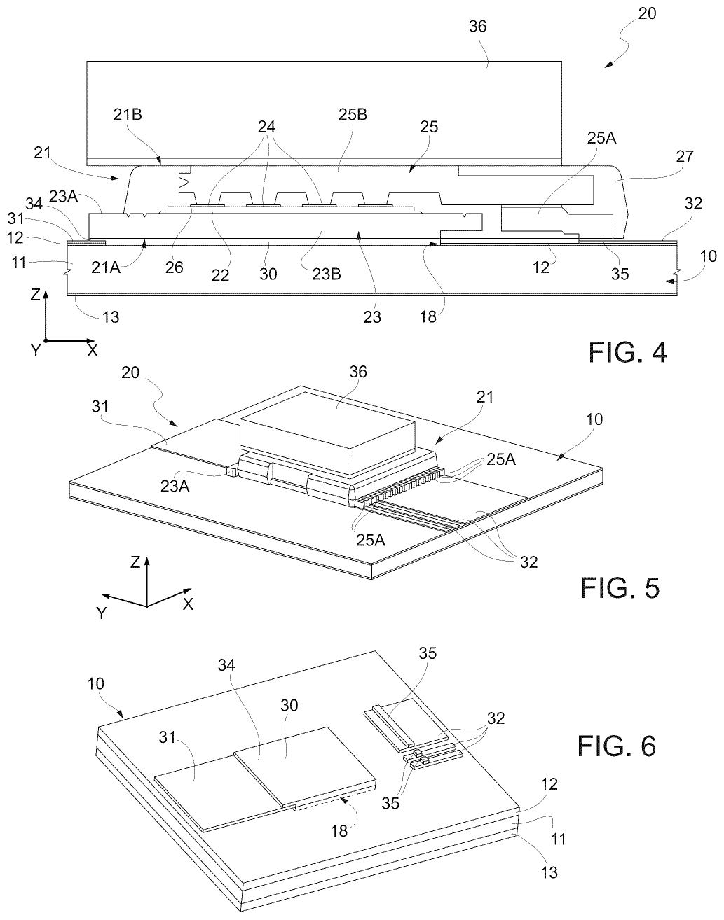

FIGS. 4-6 show a device/support assembly 20 comprising a power device 21 and the IMS support 10 of FIGS. 2-3. The power device 21 of FIGS. 4-6, for example a power transistor, is of a dual-side cooling type, with connection terminals facing a main bonding surface.

The power device 21 of FIGS. 4-6 is also of a surface mounting type.

As shown in the cross-section of FIG. 4, the power device 21 comprises a die 26 having here a first contact pad 22 on one side (in FIG. 4, at the bottom) and second contact pads 24 (in FIG. 4, at the top).

In particular, the power device 21 has three or four output leads, including a first lead 23A, typically a drain lead, and second leads 25A, typically source leads (power source leads), gate leads and possibly signal source leads.

The first lead 23A is coupled to the first contact pad 22 of the power device 21 and is part of a first connection element 23 formed by a leadframe (hereinafter also indicated by 23) also forming a dissipation region 23B.

The second leads 25A are coupled to the second contact pads 24 (not all visible). Here, the second leads 25A are part of second connection elements 25 further comprising at least one dissipation region 25B, each formed by a clip (hereinafter also indicated by 25B). Here, the second leads 25A are part of second connection elements 25 further comprising at least one dissipation region 25B, each formed by a clip (hereinafter also indicated by 25B).

The die 26 is embedded in a package 27, of electrically insulating material such as resin, generally having a parallelepiped shape and defining a first main surface 21A and a second main surface 21B of the power device 21.

The leadframe 23 is exposed and extends, level, on most of the first main surface 21A.

At least one clip 25B of the second connection elements 25 (typically, source connection elements) is exposed and level with the second main surface 21B of the power device 21. The power device 21 is therefore a double-side cooling device.

The power device 21 is bonded to an IMS support 10 having a hole 18 of dimensions (area) slightly smaller than those of the dissipation region 23B of the leadframe 23, facing the first main surface 21A of the power device 21 (area of the hole 18 slightly smaller than the facing area of the dissipation region 23B of the leadframe 23).

In the embodiment of FIGS. 4-6, an adhesive mass 30, typically an electrically and thermally conductive solder paste, completely fills the hole 18, from which it partially protrudes in height (parallel to a vertical axis Z of a Cartesian reference system XYZ) and adheres to the leadframe 23.

Furthermore, the adhesive mass 30 extends on the upper dielectric layer 12, where it forms a first adhesive region 34, as discussed hereinbelow.

In the device/support assembly 20 of FIGS. 4, 5, the connection layer 14 is already patterned and forms a first conductive track 31 and second conductive tracks 32.

The first conductive track 31 extends (after bonding the power device 21) on one side (on the left, in FIGS. 4-6) of the power device 21 and is electrically coupled to the leadframe 23 through the first adhesive region 34, arranged above the first conductive track 31 and below the first lead 23A.

The second conductive tracks 32 extend (after bonding the power device 21) on an opposite side of the power device 21 (on the right, in FIGS. 4-6) and are each electrically coupled to one or more of the second connection elements 25 through second adhesive regions 35, of electrically conductive bonding material.

In the power device 21 of FIGS. 4 and 5, a dissipative plate 36 is bonded to the second main surface 21B of the power device 21.

The adhesive mass 30, the first adhesive region 34 and the second adhesive regions 35 are formed on the IMS support 10 after defining (patterning) the conductive tracks 31 and 32, as shown in FIG. 6, which shows the IMS support 10 after defining the conductive tracks 31 and 32 from the connection layer 14 of FIG. 2 and forming the adhesive mass 30 and the adhesive regions 34, 35.

In particular, here, the adhesive mass 30 and the adhesive regions 34, 35 are formed by dispensing a same soldering material, applied in a dispensing step using a same tool, in a known manner.

In practice, here, the dissipation region 23B of the leadframe (first connection element 23) is in contact with the IMS substrate 10 and transfers heat thereto, while the dissipation region 25B of at least one of the second connection elements 25 dissipates outwards.

The device/support assembly 20 of FIGS. 4 and 5 therefore has an excellent thermal contact between the leadframe 22 and the core layer 11 of the IMS support 10, which allows a high thermal dissipation also downwards, owing to heat transfer from the power device 21 to the core layer 11.

This allows the RThj-amb (junction ambient thermal resistance) resistance to be considerably reduced with respect to devices bonded directly to the upper dielectric layer 12 (from 13% up to 30% overall).

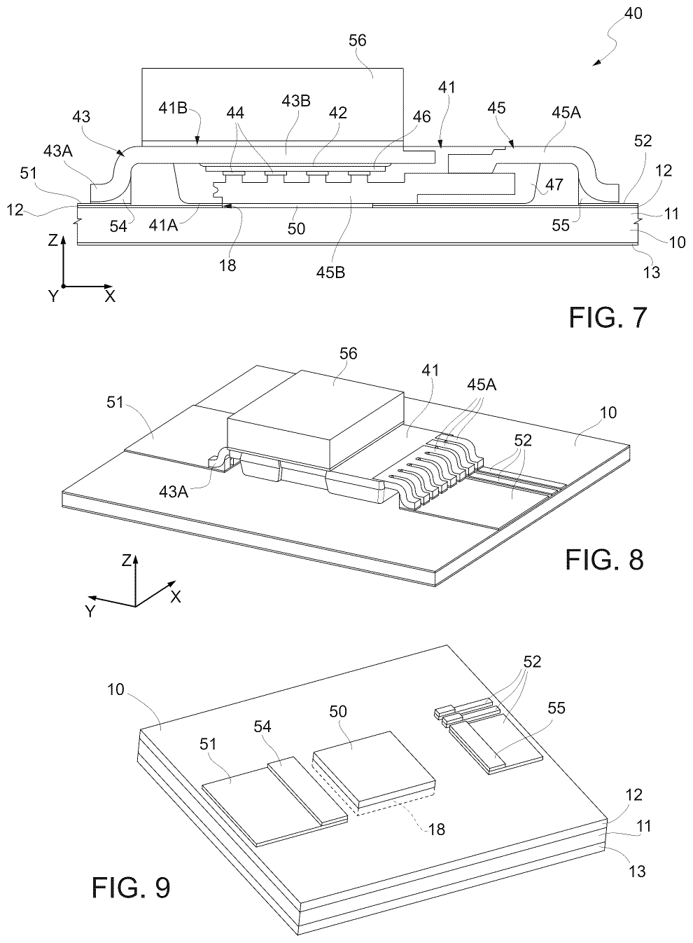

FIGS. 7 and 8 show a device/support assembly 40 in case of a power device 41 with double-side cooling, having connection terminals extending level on a main surface opposite to the bonding surface.

Also here, the power device 41 is for example a power transistor formed in a die 46 and having four terminals. Here, the terminals comprise a first connection element 43A, typically a drain connection element, coupled to a first contact pad 42, and second connection elements 45A, typically source (power source), gate and possibly additional source (signal source) connection element (see in particular FIG. 8) coupled to contact pads 44 visible only partially in FIG. 7.

The die 46 is embedded in a package 47, of electrically insulating material, generally having a parallelepiped shape, partially surrounding the connection elements 43, 45 and defining a first main surface 41A and a second main surface 41B of the power device 41.

Here, the first connection element 43 is formed into a first leadframe, is coupled with a first side (at the top in FIG. 7) of the die 46 and extends practically completely level with the second main surface 41B of the power device 41. Here, the first connection element 43 is formed in a first leadframe, is coupled with a first side (at the top in FIG. 7) of the die 46 and extends practically completely level with the second main surface 41B of the power device 41.

The second connection elements 45 are here formed by two mutually bonded portions: a first portion (dissipation region 45B), formed in a second leadframe (a comb-like leadframe), coupled to a second side of the die 46 (at the bottom in FIG. 7) and extending mainly level with the first main surface 41A of the power device 41, and a second portion (second leads 45A), formed by the first leadframe which also forms the first connection element 43, having a portion level with the second main surface 41B of the power device 41.

The power device 41 is bonded to the IMS support 10 at its first main surface 41A. Here, the hole 18 of the IMS support 10 has dimensions (area) slightly smaller than the external facing area of the dissipation region 45B′ of the second connection elements 45.

In the embodiment of FIG. 7, an adhesive mass 50, typically an electrically and thermally conductive solder paste, completely fills the hole 18, protrudes in height therefrom (along the vertical axis Z) and adheres to the dissipation region 45B of the second end connection elements 45.

The device/support assembly 40 of FIGS. 7-9 also comprises a first conductive track 51 and second conductive tracks 52, all formed by defining the connection layer 14 of FIGS. 2-3.

The conductive tracks 51 and 52 are entirely similar to the conductive tracks 31, 32 of FIG. 5 and are coupled to the first connection element 43 and, respectively, to the second connection elements 45 through a first adhesive region 54 and, respectively, second adhesive regions 54, 55. The adhesive regions 54, 55 are of bonding material, that is electrically conductive, for example the same material as the adhesive mass 50. In this embodiment, the first adhesive region 54 is distinct from the adhesive mass 50.

A dissipative plate 56 is bonded here to the second main surface 41B of the power device 41.

The adhesive mass 50, the first adhesive region 54 and the second adhesive regions 55 are formed on the IMS support 10 after defining the conductive tracks 51 and 52, as shown in FIG. 9, which shows the IMS support 10 after defining the conductive tracks 51 and 52 and forming the adhesive mass 50 and the adhesive regions 54, 55.

In particular, the adhesive mass 50 and the adhesive regions 54, 55 may be formed by dispensing a same bonding material, dispensed in a single step, in a known manner.

In practice, here, the dissipation region 45B of at least one of the second connection elements 45 is in contact with the IMS substrate 10 and transfers heat thereto, while the dissipation region 43B of the first connection element 43 dissipates outwards.

Therefore, the device/support assembly 40 of FIGS. 7 and 8 also has an excellent thermal contact between the dissipation region 45B, 43B of at least one of the second connection elements 45 and the core layer 11 of the IMS support 10. A high heat transfer from the power device 41 downwards, to the core layer 11 is thus obtained, while the first connection element 43 allows heat dissipation upwards, through the dissipative plate 56.

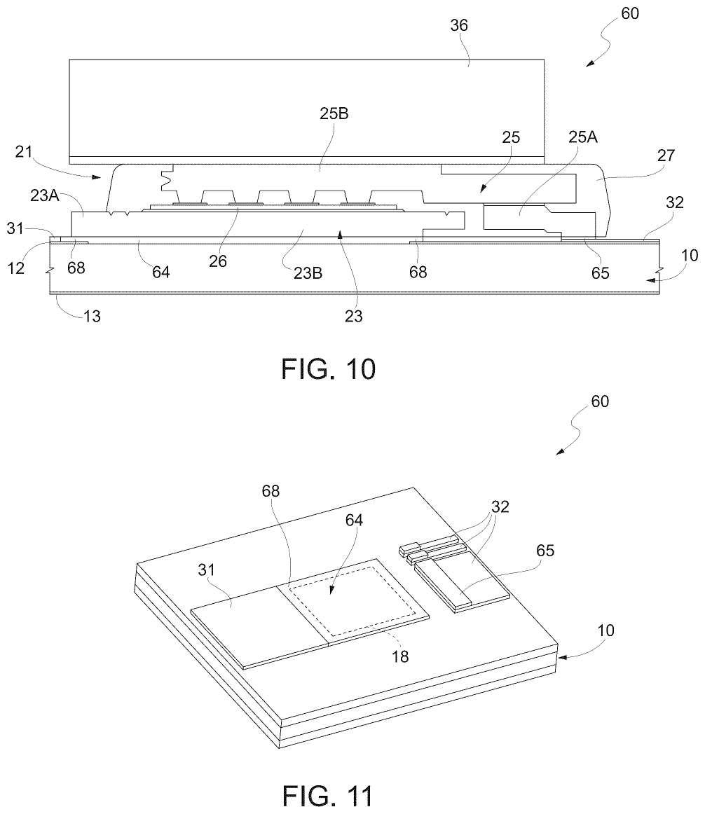

FIGS. 10 and 11 show a device/support assembly 60 comprising the power device 21 of FIG. 4 (with connection terminals extending on the main bonding surface and having double-side cooling), in case of a hole 18 that is narrower than the facing area of the dissipation region 23 of the leadframe 23.

In this case, the adhesive mass, indicated by 64, fills the hole 18 (FIG. 11) and has a collar 68 which protrudes above and laterally from the hole 18. In practice, the collar 68 extends above the upper dielectric layer 12 of the IMS support 10, as clearly visible from FIG. 11, showing the IMS support 10 after applying the soldering material to form the adhesive mass 64. Also shown in FIG. 11 are adhesive regions 65 for bonding the second connection elements 25.

Also in this case, therefore, the adhesive mass 64 also forms the first adhesive region (as in the embodiment of FIGS. 4-6, where it is indicated by 34) for bonding the first lead 23A.

In practice, the collar 68 allows direct adhesion of the power device 21 to the upper dielectric layer 12 of the IMS support 10, increasing adhesion and allowing visibility of the soldering, as desired in some applications, as well as providing high dissipation downwards, as discussed for FIGS. 4-6.

Also here, the soldering material is of an electrically conductive type and allows an electrical connection between the first lead 23A and the first conductive track 31, having the first lead 23A contiguous thereto.

In a manner not shown, the adhesive mass 50 of the device/support assembly 40 of FIGS. 7-9 may also have a collar similar to the collar 68 of FIGS. 10-11; however, for the device/support assembly 40, the first adhesive region 54 would be present, distinct from the adhesive mass 64.

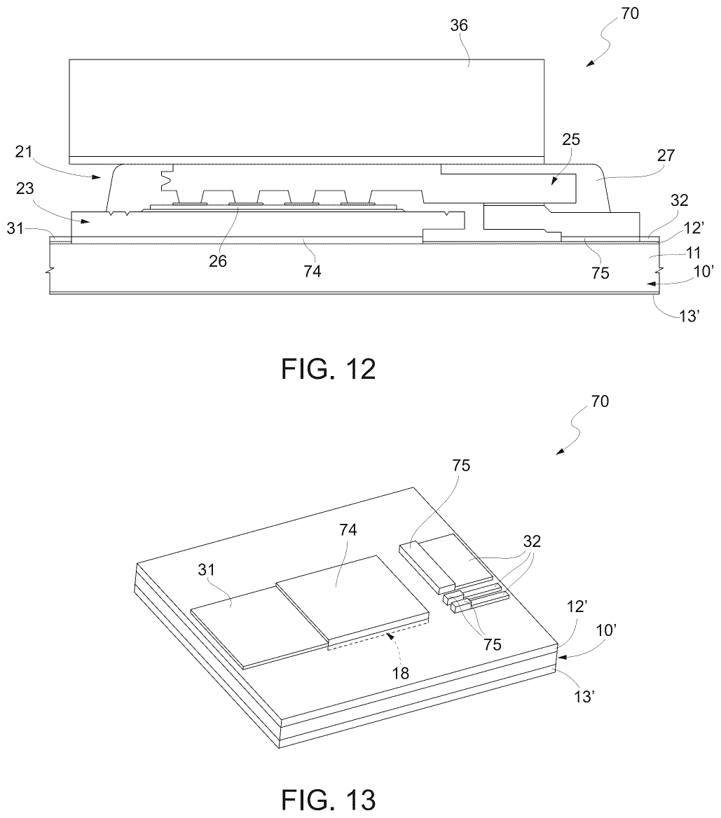

FIGS. 12 and 13 show a device/support assembly 70 comprising the power device 21 of FIG. 4 (with connection terminals extending on the main bonding surface and having double-side cooling), in the case of hole 18 having an exactly same size as the facing area of the dissipation region 23B of the leadframe 23.

Here, the upper dielectric layer, indicated by 12′, of the IMS support, indicated by 10′, is thicker than in FIG. 4, therefore the hole 18 is deeper.

The adhesive mass, indicated by 74, completely fills the hole 18 and electrically contacts the first lead 23A and the first conductive track 31 (head conductive track).

Adhesive regions 75 extend between the second leads 25B of the power device 21 and the second conductive tracks 32.

In this manner, excellent thermal dissipation is obtained.

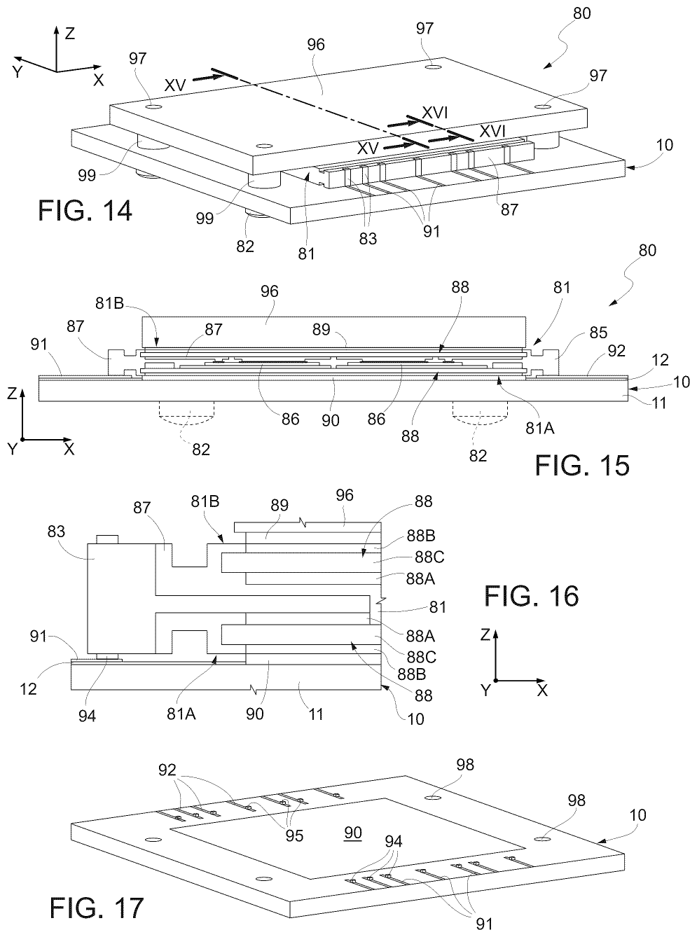

FIGS. 14-17 refer to a device/support assembly 80 in case of a power device 81 forming a module comprising a plurality of dice 86 (two visible in FIGS. 15 and 16). For example, the power device 81 may be a bridge circuit and comprise four dice 86, that are coplanar, arranged side by side two by two. Alternatively, the power device 81 may be a half-bridge circuit, with a first plurality of dice connected in parallel to each other and a second plurality of dice connected in parallel to each other.

The power device 81 has a first main surface 81A and a second main surface 81B defined by a package 87 and is bonded to the IMS support 10 of FIGS. 2-3 with the first main surface 81A.

In FIGS. 15-16, each die 86 has a plurality (typically, three) contact pads, coupled to each other and to terminals 83, 85 by metal regions formed in two DBC (Direct Bonded Copper) substrates 88.

The DBC substrates 88 are formed, in a known manner, by a first conductive layer 88A, arranged internally, of metal; by a second conductive layer 88B, arranged externally, of metal; and by an insulating layer 88C, that is intermediate, typically a ceramic layer.

The first conductive layer 88A of each DBC substrate 88 is patterned so as to couple the dice 86 according to the desired power device and the second conductive layer 88B of each DBC substrate 88 is arranged level with a respective main surface 81A, 81B of the power device 81. In particular, the second conductive layers 88B of the DBC substrates 88 may have the same area; furthermore the terminals 83, 85 are symmetrical with respect to a median horizontal plane (parallel to the horizontal plane XY) and have a height equal to the package 87 (along the vertical axis Z). In this manner, the power device 81 is reversible and may be bonded on the substrate 10 with any of the main surfaces 81A, 81B.

The terminals 83, 84 are coupled to specific regions of the first conductive layer 88A of one or both the DBC substrates 88 (in the detail of FIG. 16, of the lower DBC substrate); the material of the package 87 extends between the terminals 83, 84 (as visible in FIG. 14), ensuring good electrical insulation thereof.

The terminals 83, 84 are coupled to conductive tracks 91, 92 extending on the upper dielectric layer 12 of the IMS support 10 formed from the upper dielectric layer 12 of FIGS. 2-3. The terminals 83, 84 are bonded through adhesive regions 94, 95 similar to the adhesive regions 54, 55 of FIG. 9.

The adhesive mass, indicated here by 90, fills the hole 18 of the IMS support 10 and is in contact with the lower main surface 81A of the power device 81.

The adhesive mass 90, as well as the adhesive regions 94, 95, may be formed by a soldering material usual in the semiconductor industry, as in the preceding examples, or bonding may be performed by sintering, using a PAS—Package Attach Sintering—technique, exerting a light pressure, which compresses the sintering material. In this manner a very compact soldering is obtained, which avoids the formation of voids.

The power device 81 is bonded, on its second main surface 81B, to a dissipative plate 96, for example bonded through an adhesive layer 89. The adhesive layer 89 may be of the same bonding material as the adhesive mass 90 and the adhesive regions 94, 95. It may therefore be a soldering or sintering material.

The dissipative plate 96 and the IMS substrate 10 are here provided with holes 97, 98 allowing the passage of screws 82 and the bonding to a cooling system not shown. Possibly, bushes or hollow pillars 99 may be arranged between the dissipative plate 96 and the IMS substrate 10, in a known manner.

In the device/support assembly 80 of FIGS. 14-17, the lower dielectric layer 13 has been removed.

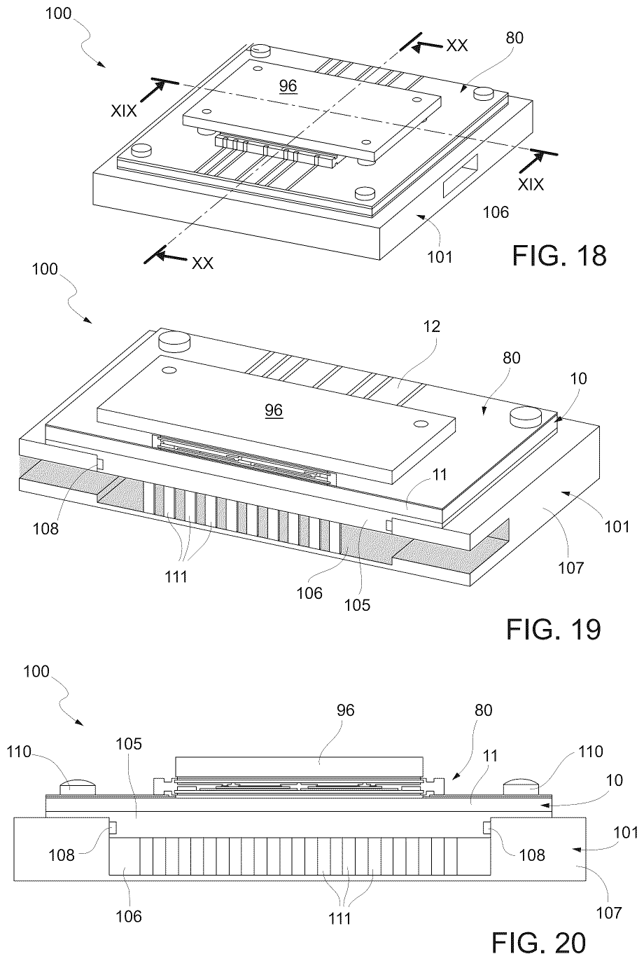

FIGS. 18-20 show an electronic system 100 comprising the device/support assembly 80 of FIGS. 14-17 and a cooling structure 101.

The cooling structure 101 is bonded to the IMS substrate 10 on its exposed side (here the lower side).

In particular, in the embodiment shown in FIGS. 18-20, the lower dielectric layer 13 of FIG. 2 is removed and the core layer 11 is bonded, for example soldered, to a closing plate 105, which upwardly closes a chamber 106 in a drawer element 107 of the cooling structure 101. The closing plate 105 is for example of metal with high thermal conduction.

The chamber 106 is open at the ends to allow the flow of a cooling fluid, for example a liquid (water or oil) or air.

Dissipation elements 111, for example fins, protrusions or pillars, extend from the lower surface of the closing plate 105 towards the inside of the chamber 106, allowing high heat removal.

A sealing element 108, for example a peripheral rubber gasket, allowing snap fitting of the closing plate 105, avoids leaks.

Screws 110 ensure a secure attachment of the device/support assembly 80 to the cooling structure 101.

In this manner there is an efficient thermal transfer from the power device 81 to the cooling structure 101, through the adhesive mass 90, the core layer 11 and the closing plate 105.

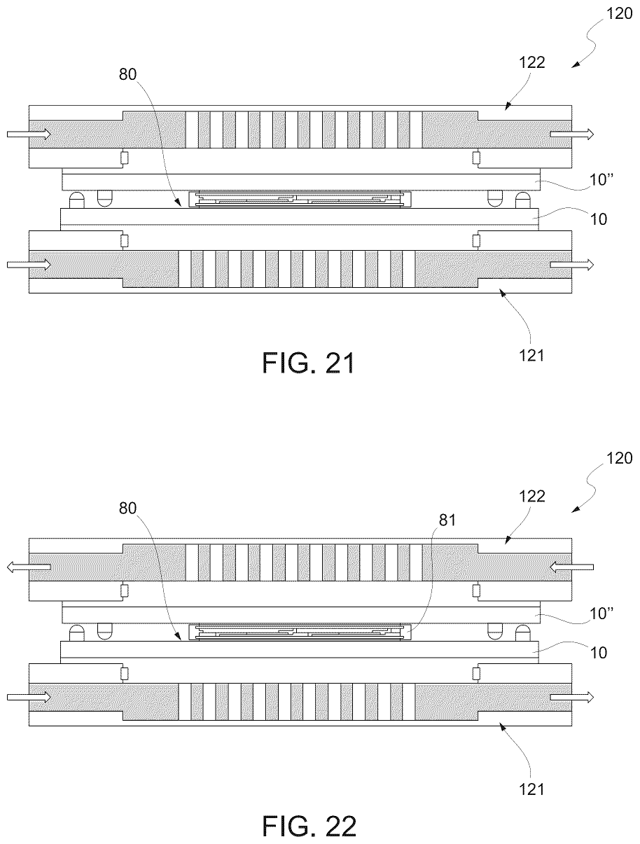

FIGS. 21, 22 show an electronic system 120 where the device/support assembly 80 of FIGS. 14-17 is attached on one side to a lower cooling structure 121 and, on an opposite side, to an upper cooling structure 122.

Here, the lower 121 and upper 122 cooling structures are the same as the cooling structure 101 of FIGS. 18-20.

In detail, the lower cooling structure 121 is attached to the IMS support 10 (hereinafter also referred to as lower IMS support 10), and the upper cooling structure 122 is attached to the device/support assembly 80 with the interposition of an upper IMS support, here indicated by 10″.

Since the power device 81 is reversible, the upper IMS support 10″ is formed like the lower IMS support 10, except for the adhesive mass 90 and the adhesive regions 94, 95 (not visible in FIGS. 21, 22), present only on one of the two IMS supports 10, 10″.

The electronic system 120 may further comprise a supply assembly and connecting elements not shown that supply the cooling fluid to the lower 121 and upper 122 cooling structures.

For example, the supply assembly may be shaped to form a circular supply system, with cooling fluid flow in the lower 121 and upper 122 cooling structures in a concordant direction, as shown in FIG. 21, or in an opposite direction, as shown in FIG. 22.

The device/support assembly described in FIGS. 4-22 allows the heat generated in the power device to be effectively transferred outwards, through the core layer 11, owing to the local removal of the upper dielectric layer 12 of the IMS support 10, 10′, 10″ and in the presence of the adhesive mass 30, 50, 64, 90, forming a low-resistance thermal path.

In particular, Applicant's studies have shown that the described device/support assembly provides a reduction in the junction-environment thermal resistance of up to 13% with respect to the use of standard IMS supports.

Finally, it is clear that modifications and variations may be made to the IMS support and the device/support assembly described and illustrated without thereby departing from the scope of the present disclosure, as defined in the attached claims. For example, the different embodiments described may be combined to provide further solutions.

For example, the collar 68 may be non-contiguous to the adhesive mass 64 of FIG. 11 and/or be interrupted, formed by a plurality of adjacent soldering points, extending all around the hole 18 or along part of the periphery of the hole 18.

In summary, the present disclosure includes the following examples.

i. A thermally conductive support (10; 10′; 10″) for electronic applications, comprising:
a core layer (11), of metal, having a first and a second face;
a dielectric layer (12; 12′), extending on the first face of the core layer (11); and
an electrical connection layer (14), of electrically conductive material, extending on the first dielectric layer (12; 12′),
wherein the dielectric layer (12; 12′) has a through hole (18) which exposes the core layer (11), the electrical connection layer (14) extending around the through hole (18).

2. The thermally conductive support according to example 1, further comprising an adhesive mass (30; 50; 64; 90) extending in the through hole (18).

3. The thermally conductive support according to the preceding example, wherein the adhesive mass (30; 50; 64; 90) completely fills the through hole (18).

4. The thermally conductive support according to example 2 or 3, comprising a collar (68) of adhesive material extending on the dielectric layer (12; 12′) and surrounding, at least partially, the through hole (18).

5. The thermally conductive support according to the preceding example, wherein the collar (68) is formed by the adhesive mass (64).

6. The thermally conductive support according to any of the preceding examples, wherein the electrical connection layer (14) is patterned and forms a plurality of electrical connection tracks (31, 32; 51, 52; 91, 92), the IMS support (10; 10′; 10″) further comprising a plurality of adhesive regions (34, 35; 54, 55; 65; 75) extending on the electrical connection tracks (31, 32; 51, 52; 91, 92), the adhesive regions (34, 35; 54, 55; 65; 75) and the adhesive mass (30; 50; 64; 74; 90) being formed by a same dispensed bonding material.

7. The thermally conductive support according to any of the preceding examples, wherein the adhesive mass (30; 50; 64; 74; 90) is of sintering or soldering material.

8. A device/support assembly (20; 40; 60; 70; 80), comprising an electronic power device (21; 41; 81) and the thermally conductive support (10; 10′, 10″) according to any of the examples 2-7, the electronic power device being packaged in a packaging mass (27; 47; 87) of electrically insulating material defining a first and a second main surface (21A, 21B; 41A, 41B; 81A, 81B), the electronic power device comprising a first dissipation region (23B; 45B; 88) surrounded by the packaging mass (27; 47; 87) and level with the first main surface (21A; 41A; 81A), wherein the first dissipation region (23B; 45B; 88) is bonded to the adhesive mass (30; 50; 64; 74; 90) of the thermally conductive support (10; 10′, 10″).

9. The device/support assembly according to the preceding example when dependent on example 6, wherein the electronic power device (21; 41) comprises a die (26; 46) having a first contact pad (22; 44), wherein a first output terminal (23A; 45A) of the electronic power device (21; 41) extends from a lateral surface of the electronic power device, is electrically coupled to the first contact pad (22; 44) through the first dissipation region (23B; 45B) and is bonded to a first electrical connection track (31; 52) of the plurality of electrical connection tracks (31, 32; 51, 52).

9bis. The device/support assembly according to the preceding example, wherein the first output terminal (23A) and the first dissipation region (23B) are formed by a leadframe (23).

9ter. The device/support assembly according to example 9, wherein the first dissipation region (45B) is formed by a leadframe or clip, the first output terminal (45A) has a portion level with the second main surface (41B) of the electronic power device (41), the first output terminal (45A) and the first dissipation region (45B) being mutually bonded.

9quater. The device/support assembly according to the preceding example, wherein the first output terminal (45A) and the second output terminal (43A) are formed in a same leadframe.

10. The device/support assembly according to example 8 or 9, when dependent on example 6, wherein the die (26; 46) comprises a second contact pad (24; 42), wherein a second output terminal (25A; 43B) of the electronic power device (21; 41) extends from the lateral surface of the electronic power device, is electrically coupled to the second contact pad (24; 42) through a second dissipation region (25B; 43B) extending level with the second main surface (21B; 41B) of the electronic power device (21; 41), and is bonded to at least one second electrical connection track (32; 51) of the plurality of electrical connection tracks (31, 32; 51, 52).

11. The device/support assembly according to the preceding example, wherein the first output terminal (23A; 45A) extends from a first side of the lateral surface and the second output terminal (25A; 43A) extends from a second side, opposite to the first side, of the lateral surface of the electronic power device (21; 41).

12. The device/support assembly according to example 8 when dependent on example 6, wherein the electronic power device is a module (81) comprising a plurality of dice (86) and a plurality of output terminals (87) extending from at least one lateral surface of the electronic power module (81), the dice (86) having respective contact pads, the output terminals (87) being electrically coupled to the contact pads and bonded to the electrical connection tracks through respective adhesive regions (91, 92).

13. The device/support assembly according to the preceding example, further comprising at least one DBC—Direct Bonded Copper—substrate (88) having a first conductive layer (88B) forming the first metal dissipation region; an intermediate insulating layer (88C) and a second conductive layer (88A) forming at least one electrical connection region coupling the contact pad of at least one die (86) of the plurality of dice (86) with at least one output terminal (87) of the plurality of output terminals.

14. An electronic system comprising the device/support assembly (80) according to example 12 or 13, comprising a first cooling structure (101; 121) attached to the core layer (11) of the thermally conductive support (10; 10′; 10″).

15. The electronic system according to the preceding example, comprising a second cooling structure (122) attached to the second main surface of the device/support assembly (80).

1. A thermally conductive support for electronic applications, comprising:
a core layer, of metal, having a first face and a second face;
a dielectric layer, extending on the first face of the core layer; and
an electrical connection layer, of electrically conductive material, extending on the first dielectric layer,
wherein the dielectric layer has a through hole which exposes the core layer, the electrical connection layer extending around the through hole.

2. The thermally conductive support of claim 1, further comprising an adhesive mass extending in the through hole.

3. The thermally conductive support of claim 1, wherein the adhesive mass completely fills the through hole.

4. The thermally conductive support of claim 2, comprising a collar of adhesive material extending on the dielectric layer and surrounding, at least partially, the through hole.

5. The thermally conductive support of claim 4, wherein the collar is formed by the adhesive mass.

6. The thermally conductive support of claim 2, wherein the electrical connection layer is patterned and forms a plurality of electrical connection tracks, the support further comprising a plurality of adhesive regions extending on the electrical connection tracks, the adhesive regions and the adhesive mass formed by a same dispensed bonding material.

7. The thermally conductive support of claim 2, wherein the adhesive mass is of sintering or soldering material.

8. A device/support assembly, comprising an electronic power device and the thermally conductive support of claim 2, the electronic power device being packaged in a packaging mass of electrically insulating material defining a first main surface and a second main surface, the electronic power device comprising a first dissipation region surrounded by the packaging mass and arranged level with the first main surface, wherein the first dissipation region is bonded to the adhesive mass of the thermally conductive support.

9. A device/support assembly of claim 8, wherein the electrical connection layer is patterned and forms a plurality of electrical connection tracks, the support further comprising a plurality of adhesive regions extending on the electrical connection tracks, the adhesive regions and the adhesive mass formed by a same dispensed bonding material, and wherein the electronic power device comprises a die having a first contact pad, wherein a first output terminal of the electronic power device extends from a lateral surface of the electronic power device, is electrically coupled to the first contact pad through the first dissipation region and is bonded to a first electrical connection track of the plurality of electrical connection tracks.

10. The device/support assembly of claim 8, wherein the electrical connection layer is patterned and forms a plurality of electrical connection tracks, the support further comprising a plurality of adhesive regions extending on the electrical connection tracks, the adhesive regions and the adhesive mass formed by a same dispensed bonding material, and wherein the die comprises a second contact pad, wherein a second output terminal of the electronic power device extends from the lateral surface of the electronic power device, is electrically coupled to the second contact pad through a second dissipation region extending level with the second main surface of the electronic power device, and is bonded to at least one second electrical connection track of the plurality of electrical connection tracks.

11. The device/support assembly of claim 10, wherein the first output terminal extends from a first side of the lateral surface and the second output terminal extends from a second side, opposite to the first side, of the lateral surface of the electronic power device.

12. The device/support assembly of claim 9, wherein the electronic power device is a module comprising a plurality of dice and a plurality of output terminals extending from at least one lateral surface of the electronic power module, the plurality of dice having respective contact pads, the plurality of output terminals electrically coupled to the contact pads and bonded to the plurality of electrical connection tracks through respective adhesive regions.

13. The device/support assembly of claim 12, further comprising at least one DBC—Direct Bonded Copper—substrate having a first conductive layer forming the first metal dissipation region; an intermediate insulating layer and a second conductive layer forming at least one electrical connection region coupling the contact pad of at least one die of the plurality of dice with at least one output terminal of the plurality of output terminals.

14. An electronic system comprising the device/support assembly of claim 12, comprising a first cooling structure attached to the core layer of the thermally conductive support.

15. The electronic system of claim 14, comprising a second cooling structure attached to the second main surface of the device/support assembly.

16. An electronic system comprising the device/support assembly of claim 13, comprising a first cooling structure attached to the core layer of the thermally conductive support.

17. The electronic system of claim 16, comprising a second cooling structure attached to the second main surface of the device/support assembly.
